(19) United States
(12) Patent Application Publication
(10) Pub. No.: US 2024/0393402 A1
(43) Pub. Date: Nov. 28, 2024

(54) BATTERY DIAGNOSIS DEVICE AND METHOD

(71) Applicants: HYUNDAI MOTOR COMPANY, Seoul (KR); Kia Corporation

(72) Inventor: Hyun Soo PARK, Seoul (KR)

(73) Assignees: HYUNDAI MOTOR COMPANY, Seoul (KR); Kia Corporation, Seoul (KR)

(21) Appl. No.: 18/371,461

(22) Filed: Sep. 22, 2023

(30) Foreign Application Priority Data
May 22, 2023 (KR) 10-2023-0065798

(51) Int. Cl. G01R 31/388; G01R 31/367; G01R 31/392; G01R 31/396

(52) U.S. Cl. CPC G01R 31/388; G01R 31/367; G01R 31/392; G01R 31/396

(57) ABSTRACT

A battery diagnosis apparatus may include a plurality of batteries, sensing units matched with the batteries on a one-to-one basis to detect a voltage or an State of charge (SOC) value of each of the batteries, and a processor. The processor is configured to determine a largest SOC deviation between a first battery and a second battery selected among the batteries, obtain a largest voltage deviation between the first battery and the second battery based on the largest SOC deviation, set a threshold value proportional to the largest voltage deviation, and diagnose whether a voltage deviation between the first battery and the second battery is abnormal by comparing a measured voltage deviation between the first battery and the second battery with the threshold value.

### CROSS-REFERENCE TO RELATED APPLICATION

The present application claims priority to Korean Patent Application No. 10-2023-0065798, filed on May 22, 2023, the entire contents of which is incorporated herein for all purposes by this reference.

### BACKGROUND OF THE PRESENT DISCLOSURE

### Field of the Present Disclosure

The present disclosure relates to a battery diagnosis apparatus and a method thereof, and to a technology for diagnosing a battery for an electric vehicle.

### Description of Related Art

An eco-friendly vehicle that utilizes electrical energy as a power source, such as an electric vehicle or a hybrid vehicle, is provided with a battery for storing and outputting electrical energy. A battery includes a plurality of battery modules, and each of the battery modules may include a plurality of battery cells. A voltage deviation occurs between battery cells due to a structure, a performance distribution between cells, a difference in deterioration, and the like, and the voltage deviation reduces power available to the battery. Therefore, it is desirable to constantly maintain the voltage of the battery modules at a predetermined level to increase the efficiency of the vehicle battery.

Therefore, a method of diagnosing whether a voltage deviation between battery modules mounted in a vehicle is greater than or equal to a predetermined level is being used.

However, the conventional method of diagnosing whether or not the voltage deviation between battery modules is abnormal includes a limitation because the conventional method does not reflect battery characteristics. That is, the battery module has time-varying battery characteristics, but the conventional method does not reflect the time-varying battery characteristics, resulting in reduction in accuracy of determining whether the battery voltage deviation is abnormal.

For example, when some of battery modules are replaced, it is highly likely that it is not possible to accurately determine whether the battery voltage deviation is abnormal due to a large difference in characteristics between the existing battery module and the replaced battery module.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a battery diagnosis device and method configured for more accurately determining whether a battery voltage deviation is abnormal by reflecting battery characteristics.

Various aspects of the present disclosure are directed to providing a battery diagnosis device and method configured for more accurately determining whether a battery voltage deviation is abnormal by reflecting a difference in battery characteristics between a replaced battery and an existing battery.

Various aspects of the present disclosure are directed to providing a battery diagnosis device and method configured for more accurately determining whether a battery voltage deviation is abnormal by reflecting battery characteristics of each of batteries

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, a battery diagnosis apparatus includes a plurality of batteries, sensing units matched with the batteries on a one-to-one basis to detect a voltage or an State of charge (SOC) value of each of the batteries, and a processor. The processor is configured to determine a largest SOC deviation between a first battery and a second battery selected among the batteries, obtain a largest voltage deviation between the first battery and the second battery based on the largest SOC deviation, set a threshold value proportional to the largest voltage deviation, and diagnose whether a voltage deviation between the first battery and the second battery is abnormal by comparing a measured voltage deviation between the first battery and the second battery with the threshold value.

According to an exemplary embodiment of the present disclosure, the processor may select a pair of batteries including a largest measured voltage deviation among the batteries as the first battery and the second battery.

According to an exemplary embodiment of the present disclosure, the processor may detect replaced batteries among the batteries, select the first battery among the replaced batteries, and select the second battery among non-replaced batteries.

According to an exemplary embodiment of the present disclosure, the processor is configured to transmit identification numbers to the sensing units, receive the identification numbers from the sensing units, and determine unidentified batteries matched with unidentified sensing units, which transmits no identification number among the sensing units, as the replaced batteries.

According to an exemplary embodiment of the present disclosure, the processor is configured to determine the largest SOC deviation in proportion to a state of health (SOH) deviation between the first battery and the second battery.

According to an exemplary embodiment of the present disclosure, the processor is configured to determine the largest SOC deviation to be proportional to a maximum available SOC range.

According to an exemplary embodiment of the present disclosure, the processor may obtain the largest voltage deviation using a table in which battery voltage values are matched according to SOC values of the plurality of batteries.

According to an exemplary embodiment of the present disclosure, the processor may set the threshold value by adding a preset fixed value and the largest voltage deviation.

According to an exemplary embodiment of the present disclosure, the processor may select a third battery and a fourth battery among the batteries, and determine whether a voltage deviation between the third battery and the fourth battery is abnormal by comparing a measured voltage deviation between the third battery and the fourth battery with the threshold value.

According to an exemplary embodiment of the present disclosure, the processor may select a third battery and a fourth battery among the plurality of batteries, set another threshold value based on a largest SOC deviation between the third battery and the fourth battery, and diagnose whether or not a voltage deviation between the third battery and the fourth battery is abnormal based on the another threshold value.

According to an aspect of the present disclosure, a battery diagnosis method includes determining a largest SOC deviation between a first battery and a second battery selected among the batteries, obtaining a largest voltage deviation between the first battery and the second battery based on the largest SOC deviation, setting a threshold value proportional to the largest voltage deviation, and diagnosing whether a voltage deviation between the first battery and the second battery is abnormal by comparing a measured voltage deviation between the first battery and the second battery with the threshold value.

According to an exemplary embodiment of the present disclosure, the determining of the largest SOC deviation may include selecting a pair of batteries including a largest measured voltage deviation among the plurality of batteries as the first battery and the second battery.

According to an exemplary embodiment of the present disclosure, the determining of the largest SOC deviation may include detecting replaced batteries among the batteries, selecting the first battery among the replaced batteries, and selecting the second battery among non-replaced batteries of the plurality of batteries.

According to an exemplary embodiment of the present disclosure, the detecting of the replaced batteries may include transmitting identification numbers to the sensing units, receiving the identification numbers from the sensing units, and determining unidentified batteries matched with unidentified sensing units, which transmits no identification number among the sensing units, as the replaced batteries.

According to an exemplary embodiment of the present disclosure, the determining of the largest SOC deviation may include determining the largest SOC deviation in proportion to a state of health (SOH) deviation between the first battery and the second battery.

According to an exemplary embodiment of the present disclosure, the determining of the largest SOC deviation may include determining the largest SOC deviation to be proportional to a maximum available SOC range.

According to an exemplary embodiment of the present disclosure, the obtaining of the largest voltage deviation may include using a table in which battery voltage values are matched according to SOC values of the plurality of batteries.

According to an exemplary embodiment of the present disclosure, the setting of the threshold value may include adding a preset fixed value and the largest voltage deviation.

According to an exemplary embodiment of the present disclosure, the battery diagnosis method may further include selecting a third battery and a fourth battery among the batteries, and diagnosing whether a voltage deviation between the third battery and the fourth battery is abnormal by comparing a measured voltage deviation between the third battery and the fourth battery with the threshold value.

According to an exemplary embodiment of the present disclosure, the battery diagnosis method may further include selecting a third battery and a fourth battery among the plurality of batteries, setting another threshold value based on a largest SOC deviation between the third battery and the fourth battery, and diagnosing whether or not a voltage deviation between the third battery and the fourth battery is abnormal based on the another threshold value.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a diagram showing a configuration of a fuel cell system including a battery diagnosis device according to an exemplary embodiment of the present disclosure;

FIG. 2 is a diagram showing a configuration of a battery device;

FIG. 3 is a diagram showing a configuration of a battery module;

FIG. 4 is a flowchart for describing a battery diagnosis method according to an exemplary embodiment of the present disclosure;

FIG. 5 is a flowchart illustrating a method of detecting a replacement module according to an exemplary embodiment of the present disclosure;

FIG. 6 is a schematic diagram showing a process of detecting a replaced module;

FIG. 7 is a flowchart for describing a method of determining a largest SOC deviation according to an exemplary embodiment of the present disclosure;

FIG. 8 is a diagram for describing the change amount in SOC according to SOH;

FIG. 9 is a diagram showing an example of the SOC-voltage table;

FIG. 10 is a flowchart for describing a battery diagnosis method according to another exemplary embodiment of the present disclosure;

FIG. 11 is a diagram for describing diagnosis timing for voltage deviation according to an exemplary embodiment of the present disclosure; and

FIG. 12 is a diagram illustrating a computing system according to an exemplary embodiment of the present disclosure.

It may be understood that the appended drawings are not necessarily to scale, presenting a somewhat simplified representation of various features illustrative of the basic principles of the present disclosure. The predetermined design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, various exemplary embodiments of the present disclosure will be described in detail with reference to the exemplary drawings. In adding the reference numerals to the components of each drawing, it should be noted that the identical or equivalent component is designated by the identical numeral even when they are displayed on other drawings. Furthermore, in describing the exemplary embodiment of the present disclosure, a detailed description of well-known features or functions will be ruled out in order not to unnecessarily obscure the gist of the present disclosure.

In describing the components of the exemplary embodiment of the present disclosure, terms such as first, second, “A”, “B”, (a), (b), and the like may be used. These terms are merely intended to distinguish one component from another component, and the terms do not limit the nature, sequence or order of the constituent components. Unless otherwise defined, all terms used herein, including technical or scientific terms, include the same meanings as those generally understood by those skilled in the art to which the present disclosure pertains. Such terms as those defined in a generally used dictionary are to be interpreted as including meanings equal to the contextual meanings in the relevant field of art, and are not to be interpreted as including ideal or excessively formal meanings unless clearly defined as including such in the present application.

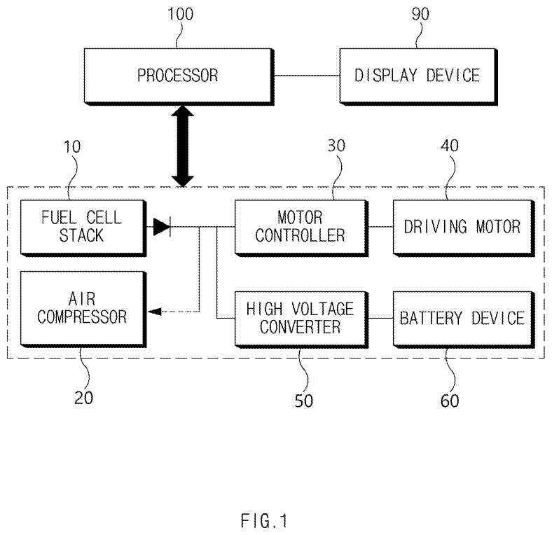

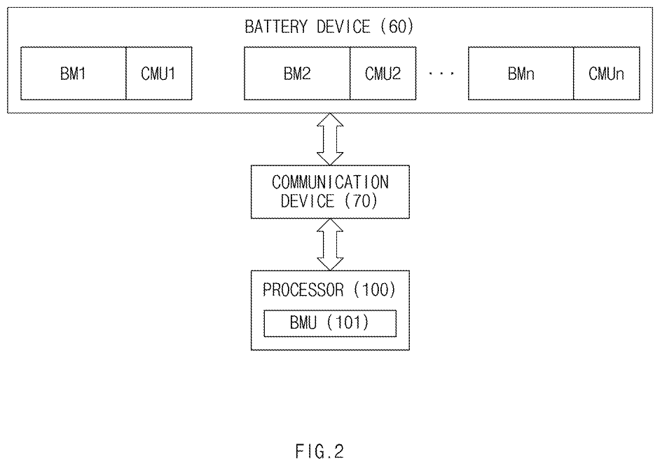

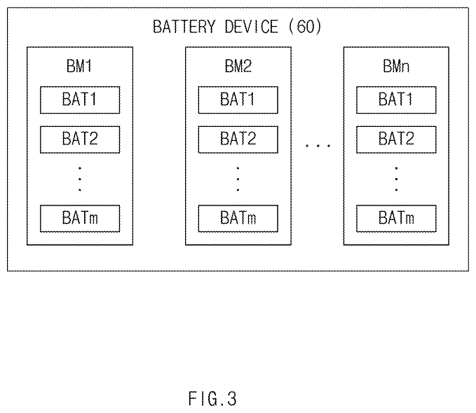

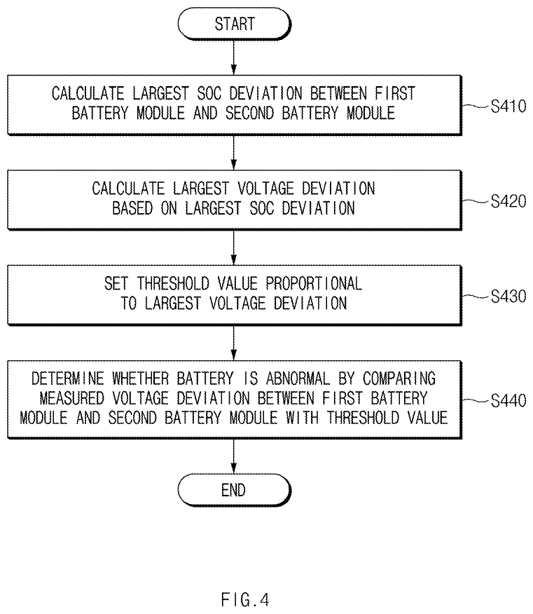

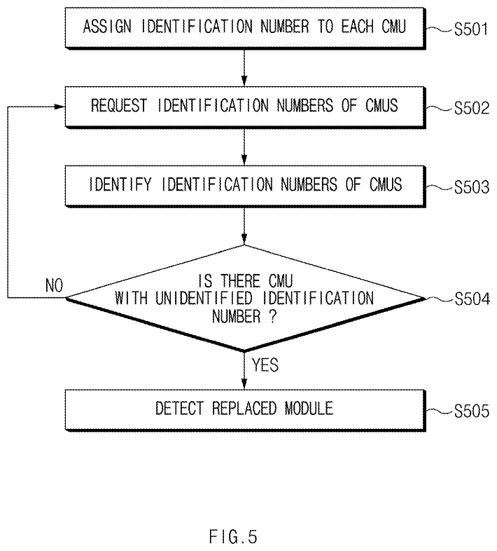

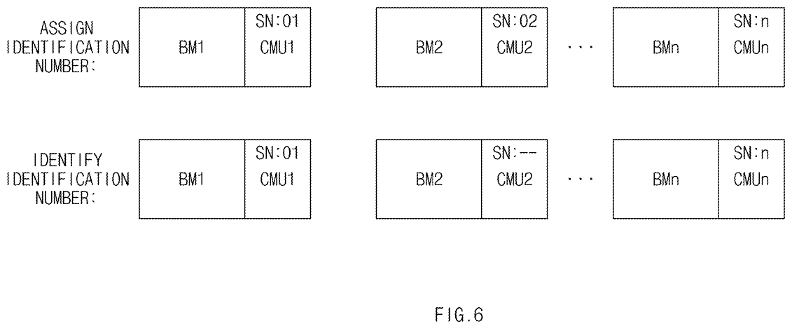

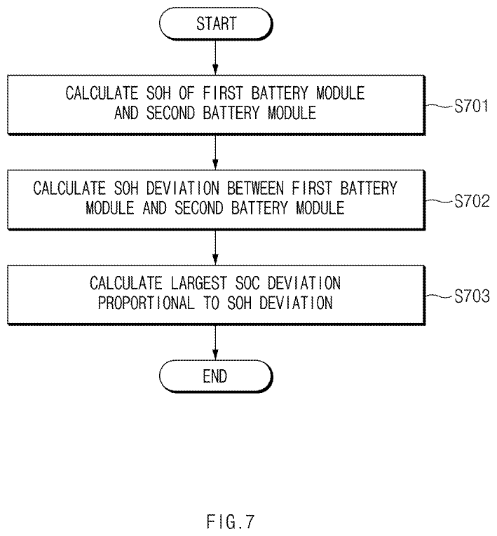

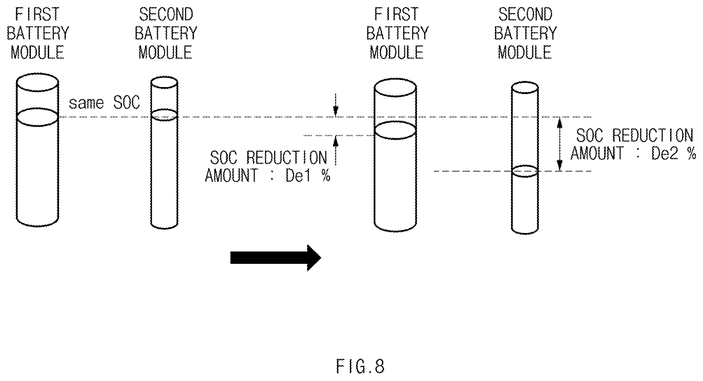

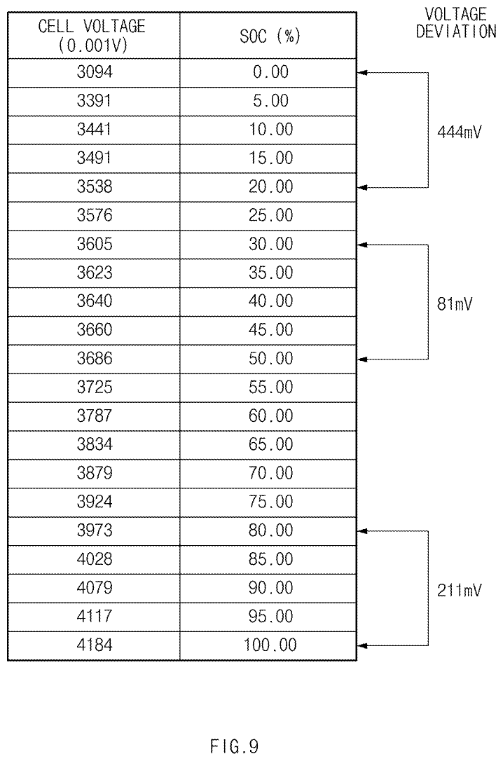

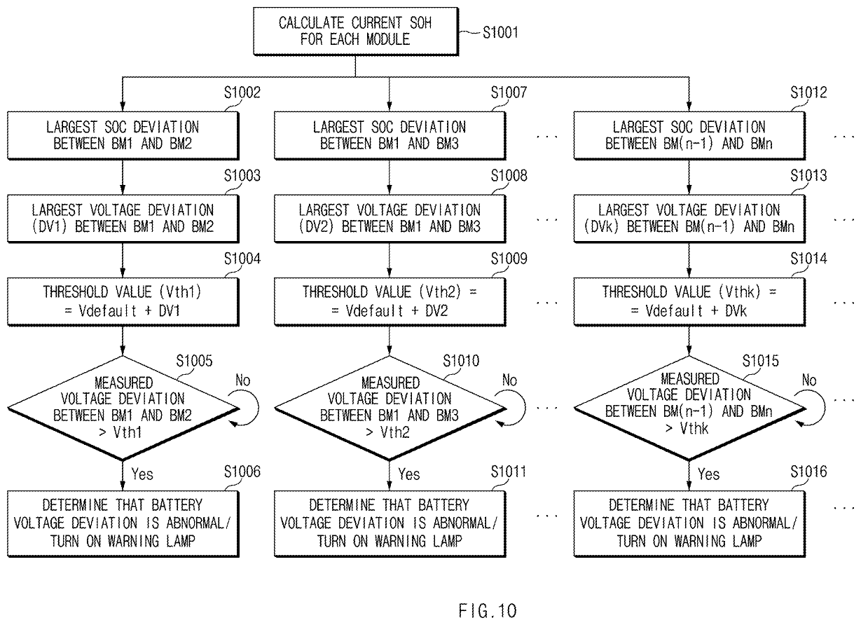

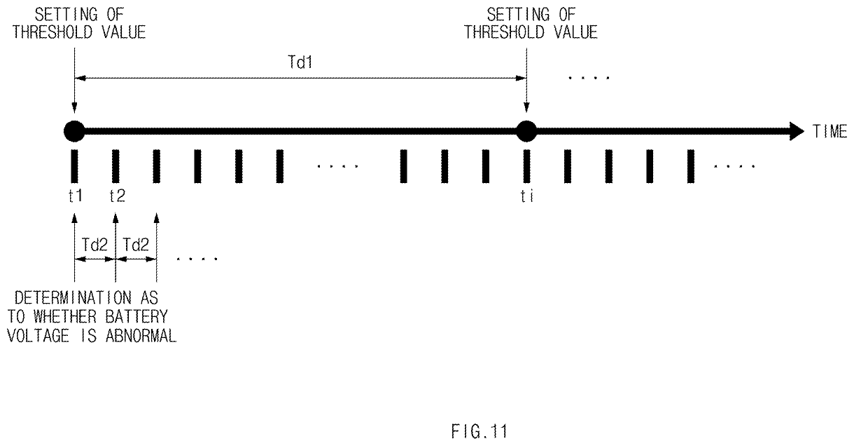

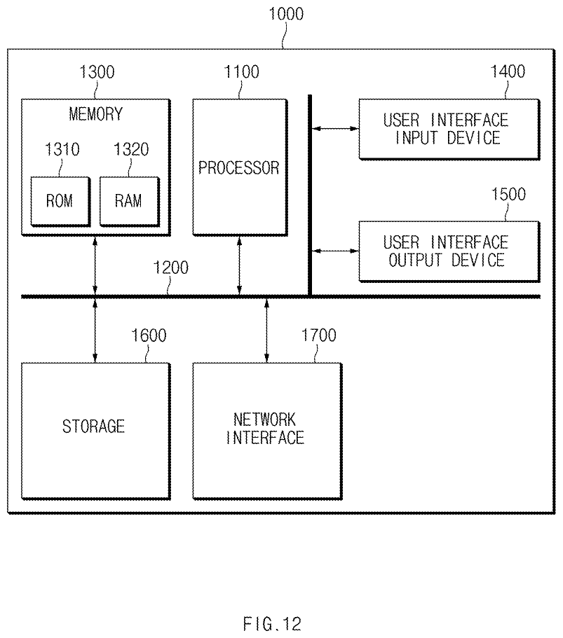

Hereinafter, various embodiments of the present disclosure will be described in detail with reference to FIG. 1, FIG. 2, FIG. 3, FIG. 4, FIG. 5, FIG. 6, FIG. 7, FIG. 8, FIG. 9, FIG. 10, FIG. 11 and FIG. 12.

FIG. 1 is a diagram showing a configuration of a fuel cell system including a battery diagnosis device according to an exemplary embodiment of the present disclosure. FIG. 2 is a diagram showing a configuration of a battery device, and FIG. 3 is a diagram showing a configuration of a battery module.

Referring to FIG. 1, FIG. 2, and FIG. 3, a battery diagnosis device according to an exemplary embodiment of the present disclosure will be described below.

Referring to FIGS. 1 to 3, a battery diagnosis device according to an exemplary embodiment of the present disclosure may include a fuel cell stack 10, an air compressor 20, a motor controller 30, a driving motor 40, a high voltage converter 50, a battery device 60, a communication device 70, and a processor 100.

The fuel cell stack 10 may be configured to generate electrical energy by allowing fuel gas to electrochemically react with oxygen. The fuel cell stack 10 may include one or more unit cells, and the unit cell may receive hydrogen gas included in the fuel gas and air and generate electrical energy by inducing oxidation and reduction reactions. The unit cell may include a membrane-electrode assembly (MEA) protected by an end plate from the outside thereof and oxidizes/reduces hydrogen gas and at least one or more separators that supply fuel gas and air to the membrane-electrode assembly.

The air compressor 20 may supply compressed air to the fuel cell stack 100. To the present end, the air compressor 20 may include a motor that rotates a fan.

The motor controller 30 may be connected to the outputs of the fuel cell stack 10 and the battery device 60 through a main bus terminal and may phase-convert power supplied from the fuel cell stack 10 or the battery device 60 to drive the drive motor 40.

The driving motor 40 may be operated by the motor controller 30 and may receive power from the fuel cell stack 10 or the battery device 60 to drive a vehicle.

The high voltage converter 500 may be a bidirectional DC converter, and may be connected to a main bus terminal of the fuel cell stack 10 to control output of the fuel cell stack 10 and the battery device 60.

The battery device 60 may be charged with power provided by the fuel cell stack 10 and may be used as an auxiliary power source for the driving motor 40.

The battery device 60 may include “n” battery modules BM1 to BMn (n is a natural number greater than or equal to 2). Each of the battery modules BM1 to BMn may include “m” battery cells BAT1 to BATm (m is a natural number greater than or equal to 2). For example, the BM1 battery module may include the first to m-th battery cells BAT1 to BATm.

Cell monitoring units CMUs may be respectively coupled to the battery modules BM1 to BMn on a to one basis. The first CMU CMU1 may detect a voltage of the first battery module BM1 and may be referred to as a sensing unit. Furthermore, the first CMU CMU1 may receive and store an identification number for identifying the first battery module BM1 from the processor 100, and transmit the identification number to the processor 100 in response to a request from the processor 100.

As shown in FIG. 2, the communication device 70 may be for communication between the CMUs and the processor 100, and may be implemented as a wired or wireless communication means. For example, the communication device 70 may support short-range communication by use of at least one of Bluetooth™, Radio Frequency Identification (RFID), Infrared Data Association (IrDA), Ultra Wideband (UWB), ZigBee, Near Field Communication (NFC), Wireless-Fidelity (Wi-Fi), Wi-Fi Direct, and Wireless Universal Serial Bus (USB) technologies.

A display device 90 may display a diagnosis result indicating whether a battery error has occurred under the control of the processor 100. The display device 90 may be a liquid crystal display (LCD) device or an organic light emitting diode (OLED) display device. The display device 90 may be a haptic device coupled to a speaker or a steering wheel.

The processor 100 may correspond to an upper controller. The processor 100 may be configured for controlling the fuel cell system, and include a battery management unit (BMU) 101 that manages the battery module.

The processor 100 may be configured to determine a largest SOC deviation between a first battery and a second battery selected among batteries. Also, the processor 100 may obtain a largest voltage deviation between the first battery and the second battery based on the largest SOC deviation, and set a threshold value proportional to the largest voltage deviation. Furthermore, the processor 100 may perform diagnosis as to whether the voltage deviation between the first battery and the second battery is abnormal by comparing the measured voltage deviation between the first battery and the second battery with a threshold value.

The first battery and the second battery may each be a battery module including a plurality of battery cells or may be a single battery cell. That is, an exemplary embodiment of the present disclosure may include processes for diagnosing whether or not the voltage deviation between battery cells is abnormal based on the largest SOC deviation between individual battery cells. Furthermore, an exemplary embodiment of the present disclosure may include processes for diagnosing whether the voltage deviation between battery modules is abnormal based on the largest SOC deviation between battery modules.

Hereinafter, a battery diagnosis process will be described focusing on the battery modules.

The processor 100 may select a first battery module and a second battery module from among battery modules. In the specification, the first battery module may be distinguished from BM1 shown in FIG. 2 and FIG. 3, and the second battery module may be distinguished from BM2 shown in FIG. 2 and FIG. 3. The first battery module may be any one of BM1 to BMn, and the second battery module may be any one of BM2 to BMn.

The processor 100 may select the first battery module and the second battery module through the measured voltages of the battery modules, the state of health (SOH) of the battery modules, or detection of replaced modules. To the present end, the processor 100 may receive voltages of battery cells provided from CMUs. Furthermore, the processor 100 may be configured to determine SOH using information such as temperature, voltage, and current provided from CMUs. Also, the processor 100 may assign identification numbers to the CMUs and detect replaced modules by identifying the identification numbers. A specific embodiment of selecting the first battery module and the second battery module will be described later.

The processor 100 may be configured to determine the largest SOC deviation in proportion to the SOH deviation between the first battery module and the second battery module. Also, the processor 100 may be configured to determine the largest SOC deviation to be proportional to the maximum available SOC. The maximum available SOC is the actual maximum SOC value of a battery module, and may vary depending on the vehicle in which the battery module is mounted.

The processor 100 may obtain a largest voltage deviation between the first battery module and the second battery module based on the largest SOC deviation. The largest voltage deviation may be obtained using an SOC-voltage table, and the SOC-voltage table may be a table in which battery cell voltages are matched according to SOC values of the plurality of batteries.

The processor 100 may set a threshold value proportional to the largest voltage deviation. For example, the processor 100 may set the threshold value by summing a preset fixed value and the largest voltage deviation.

The processor 100 may diagnose whether the voltage deviation between the first battery module and the second battery module is abnormal by comparing the measured voltage deviation between the first battery module and the second battery module with a threshold value. A process for diagnosing whether or not the voltage deviation is abnormal may be continuously performed in real time.

The processor 100 and the CMUs may include a memory for storing identification numbers and an algorithm for battery diagnosis. The memory may be implemented using a hard disk drive, flash memory, electrically erasable programmable read-only memory (EEPROM), static RAM (SRAM), ferro-electric RAM (FRAM), phase-change RAM (PRAM), magnetic RAM (MRAM), Dynamic Random Access Memory (DRAM), Synchronous Dynamic Random Access Memory (SDRAM), Double Date Rate-SDRAM (DDR-SDRAM), and the like.

Hereinafter, a battery diagnosis method according to an exemplary embodiment of the present disclosure will be described with reference to FIG. 4. FIG. 4 is a flowchart for describing a battery diagnosis method according to an exemplary embodiment of the present disclosure. It may be understood that the battery diagnosis method shown in FIG. 4 is controlled by the processor shown in FIG. 1.

Referring to FIG. 4, in S410, the processor 100 may be configured to determine a largest SOC deviation between a first battery module and a second battery module.

The first battery module and the second battery module may be a pair of battery modules selected from “n” battery modules BM1 to BMn.

The processor 100 may select the first battery module and the second battery module through the measured voltages of the battery modules, the SOH of the battery modules, or detection of a replaced module.

The processor 100 may measure the voltages of the battery modules and select a pair of battery modules including a greatest deviation between the measured voltages as a first battery module and a second battery module. That is, the first battery module may be a battery module including the largest measured voltage, and the second battery module may be a battery module including the smallest measured voltage. The battery module including the largest measured voltage may be a battery module including a battery cell including the largest measured voltage. The battery module including the smallest measured voltage may be a battery module including a battery cell including the smallest measured voltage. Alternatively, the processor 100 may select a battery module including the largest average voltage as the first battery module, and select a battery module including the smallest average voltage as the second battery module. The average voltage of a battery module may be an average of measured voltages of “m” number of battery cells included in the battery module.

Also, the processor 100 may be configured to determine the SOH of each of the battery modules and select a pair of battery modules including the largest SOH deviation as a first battery module and a second battery module. That is, the first battery module may be a battery module including the largest SOH, and the second battery module may be a battery module including the smallest SOH. The battery module including the largest SOH may be a battery module including a battery cell including the largest SOH. The battery module including the smallest SOH may be a battery module including a battery cell including the smallest SOH. To the present end, the processor 100 may be configured to determine the SOH of each of the battery modules.

Also, the processor 100 may detect a replaced module and determine the replaced module as a first battery module. Because the replaced module includes a larger measured voltage and SOH than non-replaced battery modules, the replaced module may be regarded as a first battery module.

The processor 100 may be configured to determine a largest state of charge (SOC) deviation between the first battery module and the second battery module. The largest SOC deviation between the first battery module and the second battery module may be the SOC value of the first battery module when the SOC reduction amount of the second battery module is 100 (%) in a state where the SOCs of the first battery module and the second battery module are 100%.

The processor 100 may be configured to determine the largest SOC deviation so that the largest SOC deviation is proportional to the SOH deviation.

Also, the processor 100 may be configured to determine the largest SOC deviation to be proportional to a maximum available SOC range.

In S420, the processor 100 may obtain a largest voltage deviation between the first battery module and the second battery module based on the largest SOC deviation.

The processor 100 may be configured to determine the largest voltage deviation using the SOC-voltage table.

In S430, the processor 100 may set a threshold value proportional to the largest voltage deviation.

The processor 100 may set the threshold value by summing a fixed value and the largest voltage deviation. The fixed value may be a preset voltage.

In S440, the processor 100 may diagnose whether the battery module is abnormal using the threshold value.

After setting the threshold value, the processor 100 may diagnose whether the voltage deviation of each of pairs of battery modules is abnormal using the threshold value in units of a predetermined time period.

The processor 100 may diagnose that a voltage deviation between the first battery module and the second battery module is abnormal when the measured voltage deviation between the first battery module and the second battery module is greater than or equal to the threshold value.

Furthermore, the processor 100 may diagnose whether the voltage deviation of each of other pairs of battery modules is abnormal by use of a threshold value generated based on the largest SOC deviation between the first battery module and the second battery module. For example, in FIG. 2, when BM1 is a first battery module and BM2 is a second battery module, the processor 100 may diagnose whether there is a voltage deviation between the battery module BM1 and the battery module BM3 and there is a voltage deviation between the battery module BM1 and the battery module Bmn, by use of the threshold value.

S440 may be performed at timing different from S410 to S430.

In S440, the measured voltage of the first battery module may be the largest voltage among the measured voltages of the battery cells belonging to the first battery module, and the measured voltage of the second battery module may be the smallest voltage among the measured voltages of the battery cells belonging to the second battery module.

Hereinafter, detailed embodiments of the processes shown in FIG. 4 will be described.

An exemplary embodiment of detecting a replaced module will be described with referenced to FIG. 5 and FIG. 6.

FIG. 5 is a flowchart illustrating a method of detecting a replacement module according to an exemplary embodiment of the present disclosure, and FIG. 6 is a schematic diagram illustrating a process of detecting a replacement module.

Referring to FIG. 5 and FIG. 6, in S501, the processor 100 may assign identification numbers to CMUs CMU1 to CMUn.

To the present end, the processor 100 may transmit unique identification numbers (serial number; SN) to the CMUs (CMU1 to CMUn) through the communication device 70, respectively. For example, the processor 100 may transmit an identification number of “01” to the first CMU CMU1 and transmit an identification number of “02” to the second CMU CMU2. Similarly, an identification number of “n” may be assigned to the n-th CMU (CMUn).

The processor 100 may store identification numbers provided from the communication device 70 in a memory.

In S502, the processor 100 may request an identification number from the CMUs (CMU1 to CMUn).

The processor 100 may request identification numbers from the CMUs (CMU1 to CMUn) based on a specific event, such as when ignition On (IG On) is started.

Alternatively, the processor 100 may request identification numbers from the CMUs (CMU1 to CMUn) at regular intervals in the ignition-on state.

The CMUs (CMU1 to CMUn) may transmit the identification numbers stored in the memory in response to the request for identification number from the processor 100.

In S503, the processor 100 may identify the identification numbers provided from the CMUs (CMU1 to CMUn).

In S504, the processor 100 may be configured to determine whether there is a CMU whose identification number is not identified.

In S504, if there is not a CMU with unidentified identification no, the process will go to S502.

In S505, the processor 100 may detect a CMU whose identification number is not identified as a replacement module. For example, when an identification number is not provided from the second CMU (CMU2) as shown in FIG. 6, the processor 100 may be configured to determine that the second CMU (CMU2) is a replacement module.

FIG. 7 is a flowchart for describing a method of determining a largest SOC deviation according to an exemplary embodiment of the present disclosure. A method of determining a largest SOC deviation will be described below with reference to FIG. 7.

In S701, the processor 100 may be configured to determine the SOH of a first battery module and the SOH of a second battery module.

To determine the SOH, the processor 100 may consider a battery's internal resistance, battery capacity, voltage, self-discharge, charge/discharge count, and the like.

When the first battery module and the second battery module are determined based on measured voltages or whether the battery is a replaced module, the processor 100 may be configured to determine SOHs of the first battery module and the second battery module as determined.

Alternatively, when determining the first battery module and the second battery module based on the SOH, the processor 100 may be configured to determine the SOHs of n×m battery cells. Also, the processor 100 may be configured to determine the largest value of the n×m determined values for SOH as the SOH of the first battery module, and determine the smallest value as the SOH of the second battery module.

In S702, the processor 100 may be configured to determine a deviation between the SOH of the first battery module and the SOH of the second battery module.

In S703, the processor 100 may be configured to determine a largest SOC deviation proportional to the SOH deviation between the first battery module and the second battery module. A method of determining the largest SOC deviation will be described in detail with reference to FIG. 8.

FIG. 8 is a diagram for describing the change amount in SOC according to SOH.

Referring to FIG. 8, SOH of a first battery module (SOH1) may be greater than SOH of the second battery module (SOH2). When the first battery module and the second battery module consume the same power in the same SOC state, the SOC reduction amount may be different. That is, an SOC reduction amount De1 of the first battery module may be smaller than an SOC reduction amount De2 of the second battery module.

Because it is assumed that the first battery module and the second battery module consume the same power, it may be expressed as “SOH1×De1=SOH2×De2”. Accordingly, the SOC reduction amount De1 of the first battery module may be expressed as “De2×(SOH2/SOH1)”. When the first battery module is a replaced module, the SOH (SOH1) of the first battery module may be estimated as 100, and the SOC reduction amount De1 of the first battery module may be expressed as “De2×(SOH2/100)”.

Accordingly, the SOC deviation between the first battery module and the second battery module may be expressed as “De2−De1=De2−De2×(SOH2/SOH1)=De2×(SOH1−SOH2)/SOH1”. The SOC deviation between the first battery module and the second battery module may correspond to a case where the second battery module is fully discharged. That is, the largest SOC deviation between the first battery module and the second battery module may be a case where De2 is 100. When the SOC reduction amount De2 of the second battery module is 100, the SOC reduction amount De1 of the first battery module may be expressed as “(SOH1−SOH2)/SOH1”. Accordingly, the largest SOC deviation between the first battery module and the second battery module may be expressed as “(SOH1−SOH2)/SOH1”.

Also, according to an exemplary embodiment of the present disclosure, the processor 100 may reflect a maximum available SOC in a process of determining the largest SOC deviation. As a result, the processor 100 may be configured to determine the largest SOC deviation as shown in [Equation 1] below.

$$Largest SOC deviation = Maximum available SOC \times \frac{S O H 1 - S O H 2}{S O H 1} \qquad [ Equation 1 ]$$

For example, when the maximum available SOC value of the battery module is 97 (%), the SOH of the first battery module (SOH1 ) is 95 (%), and the SOH of the second battery module (SOH2) is 90 (%), the largest SOC deviation between the first battery module and the second battery module may be determined as “97×(95−90)/95=5.1”.

FIG. 9 is a diagram showing an example of the SOC-voltage table. FIG. 9 is a diagram for describing a method of obtaining a largest voltage deviation.

Referring to FIG. 9, the SOC-voltage table may be a table in which a battery cell voltage is matched with each SOC. The battery cell voltage may include a larger magnitude as the SOC increases, but the change rate in the battery cell voltage may vary according to SOC sections.

For example, a case where the SOC deviation is 20 (%) is described below.

When the SOC is 0, a cell voltage may be 3094 (mV), whereas when the SOC is 20, the cell voltage may be 3538 (mV) and the voltage deviation may be 444 (mV). When the SOC is 30, the cell voltage may be 3605 (mV), whereas when the SOC is 50, the cell voltage may be 3686 (mV), and the voltage deviation may be 81 (mV). When the SOC is 80, the cell voltage may be 3973 (mV), whereas when the SOC is 100, the cell voltage may be 4184 (mV), and the voltage deviation may be 211 (mV). Although the above-described three cases identically represent that the SOC deviation is 20 (%), the voltage deviation may be different.

The processor 100 may search the SOC-voltage table for a region including the largest cell voltage according to the SOC deviation corresponding to the largest SOC deviation. For example, when the largest SOC deviation is 20 (%) and the SOC-voltage table is as shown in FIG. 9, the processor 100 may be configured to determine the largest voltage deviation as 444 (mV).

FIG. 10 is a flowchart for describing a battery diagnosis method according to another exemplary embodiment of the present disclosure. FIG. 10 illustrates an exemplary embodiment configured for more accurately determining whether voltage deviations between battery modules of various pairs are abnormal.

In the exemplary embodiment shown in FIG. 4, the processor 100 may diagnose whether voltage deviations of all pairs of battery modules are abnormal, using one threshold value. Because the threshold set in the exemplary embodiment shown in FIG. 4 is determined using SOH deviations of pairs of battery modules including the largest SOH deviation, the magnitude of the threshold value may be set somewhat higher. Accordingly, accuracy may be somewhat deteriorated in determining whether voltage deviations of pairs of battery modules including a smaller SOH deviation are abnormal.

Referring to FIG. 10, a battery diagnosis method according to another exemplary embodiment will be described below.

In S1001, the processor 100 may be configured to determine the SOH of each of “n” battery modules BM1 to BMn. To the present end, the processor 100 may be configured to determine the SOHs of “m” battery cells belonging to each of the “n” battery modules BM1 to BMn. Furthermore, the processor 100 may select a representative value from the SOHs of the battery cells and determine the selected representative value as the SOH of a corresponding battery module. The representative value may be a largest value, a minimum value or an average value. For example, the processor 100 may be configured to determine the SOH of each of “m” battery cells belonging to BM1 and determine the SOH with the largest value as the SOH of BM1. Alternatively, the processor 100 may be configured to determine the SOH with the smallest value among the SOHs of the “m” battery cells belonging to BM1 as the SOH of BM1. Alternatively, the processor 100 may be configured to determine the SOH of BM1 by averaging the SOHs of the “m” battery cells belonging to BM1.

In S1002, the processor 100 may be configured to determine a largest SOC deviation between BM1 and BM2. The processor 100 may be configured to determine the largest SOC deviation using the process shown in FIG. 7.

In S1003, the processor 100 may be configured to determine a largest voltage deviation DVI between BM1 and BM2. The processor 100 may be configured to determine the largest voltage deviation using the SOC-voltage table as shown in FIG. 9.

In S1004, the processor 100 may be configured to determine a first threshold value Vth1. The processor 100 may be configured to determine the first threshold value Vth1 by adding a preset fixed value and the largest voltage deviation DVI between BM1 and BM2 determined in S1003.

In S1005, the processor 100 may be configured to determine whether the measured voltage deviation between BM1 and BM2 is greater than or equal to the first threshold value Vth1.

In S1006, the processor 100 may be configured to determine that the voltage deviation between BM1 and BM2 is abnormal when the measured voltage deviation between BM1 and BM2 is greater than or equal to the first threshold value Vth1. Furthermore, when the processor 100 determines that the voltage deviation between BM1 and BM2 is abnormal, the processor 100 may notify an abnormal voltage deviation through the display device 90.

Similarly to S1002 to S1006, the processor 100 may proceed with S1007 to S1011 to determine whether or not the voltage deviation between BM1 and BM3 is abnormal. A second threshold Vth2 used in a process of determining whether the voltage deviation between BM1 and BM3 is abnormal may be determined based on the largest SOC deviation between BM1 and BM3. Therefore, it is possible to more accurately determine whether or not the voltage deviation between BM1 and BM3 is abnormal than using the first threshold value Vth1 because the SOH characteristics between BM1 and BM3 is more accurately reflected in S1011.

Similarly, the processor 100 may proceed with S1012 to S1016 to determine whether the voltage deviation between BM(n-1) and Bmn is abnormal. The processor 100 may be configured to determine whether the voltage deviation between BM(n-1) and BMn is abnormal by use of the k-th threshold value (k is a natural number) that more accurately reflects the SOH characteristics between BM(n-1) and BMn.

FIG. 11 is a diagram for describing diagnosis timing for voltage deviation according to an exemplary embodiment of the present disclosure.

Referring to FIG. 11, the processor 100 may set a threshold value at timing t1 and timing ti (i is a natural number).

After setting the threshold value, the processor 100 may be configured to determine whether a battery voltage is abnormal at timing t1 and timing t2.

A period Td2 for determining whether the battery voltage is abnormal may be very short compared to a period Td1 for setting the threshold value. That is, after setting the threshold value, the processor 100 may diagnose whether a voltage deviation between battery modules is abnormal using the set threshold value within a predetermined time period.

When the predetermined time period has elapsed, not only is there a possibility that a battery has been replaced, but the SOHs of the batteries may be changed. Accordingly, the processor 100 may set the threshold value again.

FIG. 12 illustrates a computing system according to an exemplary embodiment of the present disclosure.

Referring to FIG. 12, a computing system 1000 may include at least one processor 1100, a memory 1300, a user interface input device 1400, a user interface output device 1500, storage 1600, and a network interface 1700, which are connected to each other via a bus 1200.

The processor 1100 may be a central processing unit (CPU) or a semiconductor device that processes instructions stored in the memory 1300 and/or the storage 1600. The memory 1300 and the storage 1600 may include various types of volatile or non-volatile storage media. For example, the memory 1300 may include a Read Only Memory (ROM) and a Random Access Memory (RAM).

Thus, the operations of the method or the algorithm described in connection with the exemplary embodiments included herein may be embodied directly in hardware or a software module executed by the processor 1100, or in a combination thereof. The software module may reside on a storage medium (that is, the memory 1300 and/or the storage 1600) such as a RAM, a flash memory, a ROM, an EPROM, an EEPROM, a register, a hard disk, a removable disk, and a CD-ROM.

The exemplary storage medium may be coupled to the processor 1100, and the processor 1100 may read information out of the storage medium and may record information in the storage medium. Alternatively, the storage medium may be integrated with the processor 1100. The processor and the storage medium may reside in an application specific integrated circuit (ASIC). The ASIC may reside within a user terminal. In another case, the processor and the storage medium may reside in the user terminal as separate components.

The above description is merely illustrative of the technical idea of the present disclosure, and various modifications and variations may be made without departing from the essential characteristics of the present disclosure by those skilled in the art to which the present disclosure pertains.

Therefore, the exemplary embodiments of the present disclosure are provided to explain the spirit and scope of the present disclosure, but not to limit them, so that the spirit and scope of the present disclosure is not limited by the embodiments. The scope of protection of the present disclosure should be interpreted by the following claims, and all technical ideas within the scope equivalent thereto should be construed as being included in the scope of the present disclosure.

According to the exemplary embodiment of the present disclosure, it is possible to determine whether or not the battery voltage deviation is abnormal by reflecting a deviation in the aging degree of batteries, thus performing battery diagnosis more accurately.

According to the exemplary embodiment of the present disclosure, it is possible to determine whether the battery voltage deviation is abnormal by reflecting a deviation in the aging degree between the replaced battery and the existing battery, thus performing battery diagnosis more accurately.

According to the exemplary embodiment of the present disclosure, it is possible to determine whether or not the battery voltage deviation is abnormal by reflecting a deviation in the aging degree of each pair of batteries, thus performing battery diagnosis more accurately.

Furthermore, various effects may be provided that are directly or indirectly understood through the present disclosure.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In the present specification, unless stated otherwise, a singular expression includes a plural expression unless the context clearly indicates otherwise.

In exemplary embodiments of the present disclosure, “at least one of A and B” may refer to “at least one of A or B” or “at least one of combinations of one or more of A and B”. In addition, “one or more of A and B” may refer to “one or more of A or B” or “one or more of combinations of one or more of A and B”.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A battery diagnosis apparatus comprising:
a plurality of batteries:
sensing units matched with the batteries on a one-to-one basis to detect a voltage or an State of charge (SOC) value of each of the batteries; and
a processor configured to:
determine a largest SOC deviation between a first battery and a second battery selected among the batteries,
obtain a largest voltage deviation between the first battery and the second battery based on the largest SOC deviation,
set a first threshold value proportional to the largest voltage deviation, and
diagnose whether a voltage deviation between the first battery and the second battery is abnormal by comparing a measured voltage deviation between the first battery and the second battery with the first threshold value.

2. The battery diagnosis apparatus of claim 1, wherein the processor is further configured to select a pair of batteries including a largest measured voltage deviation among the batteries as the first battery and the second battery.

3. The battery diagnosis apparatus of claim 1, wherein the processor is further configured to:
detect replaced batteries among the batteries,
select the first battery among the replaced batteries, and
select the second battery among non-replaced batteries of the plurality of batteries.

4. The battery diagnosis apparatus of claim 3, wherein the processor is further configured to:
transmit identification numbers to the sensing units,
receive the identification numbers from the sensing units, and
determine unidentified batteries matched with unidentified sensing units, which transmits no identification number among the sensing units, as the replaced batteries.

5. The battery diagnosis apparatus of claim 1, wherein the processor is further configured to determine the largest SOC deviation in proportion to a state of health (SOH) deviation between the first battery and the second battery.

6. The battery diagnosis apparatus of claim 5, wherein the processor is further configured to determine the largest SOC deviation to be proportional to a maximum available SOC range.

7. The battery diagnosis apparatus of claim 1, wherein the processor is further configured to obtain the largest voltage deviation using a table in which battery voltage values are matched according to SOC values of the plurality of batteries.

8. The battery diagnosis apparatus of claim 1, wherein the processor is further configured to set the first threshold value by adding a preset fixed value and the largest voltage deviation.

9. The battery diagnosis apparatus of claim 1, wherein the processor is further configured to:
select a third battery and a fourth battery among the batteries, and
determine whether a voltage deviation between the third battery and the fourth battery is abnormal by comparing a measured voltage deviation between the third battery and the fourth battery with the first threshold value.

10. The battery diagnosis apparatus of claim 1, wherein the processor is further configured to:
select a third battery and a fourth battery among the plurality of batteries,
set a second threshold value based on a largest SOC deviation between the third battery and the fourth battery, and
diagnose whether or not a voltage deviation between the third battery and the fourth battery is abnormal based on the second threshold value.

11. A battery diagnosis method comprising:
determining, by a processor, a largest SOC deviation between a first battery and a second battery selected among the batteries;
obtaining, by the processor, a largest voltage deviation between the first battery and the second battery based on the largest SOC deviation;
setting, by the processor, a first threshold value proportional to the largest voltage deviation; and
diagnosing, by the processor, whether a voltage deviation between the first battery and the second battery is abnormal by comparing a measured voltage deviation between the first battery and the second battery with the first threshold value.

12. The battery diagnosis method of claim 11, wherein the determining of the largest SOC deviation includes selecting a pair of batteries including a largest measured voltage deviation among the plurality of batteries as the first battery and the second battery.

13. The battery diagnosis method of claim 11, wherein the determining of the largest SOC deviation includes:
detecting replaced batteries among the batteries;
selecting the first battery among the replaced batteries; and
selecting the second battery among non-replaced batteries of the plurality of batteries.

14. The battery diagnosis method of claim 13, wherein the detecting of the replaced batteries includes:
transmitting identification numbers to the sensing units;
receiving the identification numbers from the sensing units; and
determining unidentified batteries matched with unidentified sensing units, which transmits no identification number among the sensing units, as the replaced batteries.

15. The battery diagnosis method of claim 11, wherein the determining of the largest SOC deviation includes determining the largest SOC deviation in proportion to a state of health (SOH) deviation between the first battery and the second battery.

16. The battery diagnosis method of claim 15, wherein the determining of the largest SOC deviation includes determining the largest SOC deviation to be proportional to a maximum available SOC range.

17. The battery diagnosis method of claim 11, wherein the obtaining of the largest voltage deviation includes using a table in which battery voltage values are matched according to SOC values of the plurality of batteries.

18. The battery diagnosis method of claim 11, wherein the setting of the first threshold value includes adding a preset fixed value and the largest voltage deviation.

19. The battery diagnosis method of claim 12, further including:
selecting a third battery and a fourth battery among the batteries; and
diagnosing whether a voltage deviation between the third battery and the fourth battery is abnormal by comparing a measured voltage deviation between the third battery and the fourth battery with the first threshold value.

20. The battery diagnosis method of claim 12, further including:
selecting a third battery and a fourth battery among the plurality of batteries;
setting a second threshold value based on a largest SOC deviation between the third battery and the fourth battery; and
diagnosing whether or not a voltage deviation between the third battery and the fourth battery is abnormal based on the second threshold value.
